(19) United States
(12) Patent Application Publication
(10) Pub. No.: US 2006/0197619 A1
(43) Pub. Date: Sep. 7, 2006

(54) Piezoelectric oscillator and manufacturing method thereof

(75) Inventors: Daisuke Oishi, Ebina-shi (JP); Makoto Komai, Chigasaki-shi (JP)

Correspondence Address: OLIFF & BERRIDGE, PLC, P.O. BOX 19928, ALEXANDRIA, VA, 22320, US

(73) Assignee: EPSON TOYOCOM CORPORATION, Kawasaki-shi (JP)

(21) Appl. No.: 11/329,237

(22) Filed: Jan. 11, 2006

(30) Foreign Application Priority Data
Jul. 12, 2004 (JP) 2004-205118

(51) Int. Cl. H03B 5/32

(52) U.S. Cl. 331/158

(57) ABSTRACT

[Problem] To provide a method of manufacturing a piezoelectric oscillator capable of preventing poor DLD characteristics that tend to occur in the piezoelectric oscillator including a piezoelectric resonator element and an IC chip that are sealed in the same package. [Means to Solve the Problem]

A step of chemically polishing a surface without an integrated circuit of a silicon wafer 31 (step S2), a step of cleaning the silicon wafer 31 (step S3), a step of cutting the silicon wafer 31 into individual pieces of IC chip 6 (step S5), a step of bonding the IC chip 6 facing downwards in a recessed section of an insulating container, a step of mounting a piezoelectric resonator element in the insulating container, and a step of sealing with metal cover are included.

### TECHNICAL FIELD

The present invention relates to a method of manufacturing a piezoelectric oscillator for surface mounting, and more particularly to a piezoelectric oscillator manufacturing method capable of preventing problems that tend to occur in a piezoelectric oscillator including a piezoelectric resonator element and an IC chip both sealed in the same package, that is, poor DLD characteristics caused by abrasives or shavings produced in processing semiconductor materials being attached to a piezoelectric resonator element.

### BACKGROUND ART

In association with popularization of mobile communication devices such as cellular phones, reduction in price and size of the mobile communication devices have been rapidly progressed, and thus demands for reduction in price, size, and thickness of piezoelectric oscillators such as quartz crystal oscillators used for these communication devices have also increased.

To meet such demands, a surface mounting type piezoelectric oscillator as shown in FIG. 6 has been suggested. This piezoelectric oscillator includes an insulating container 100 that has a recessed section 101 at the top surface and external electrodes 102 for surface mounting on the bottom, an IC chip 110 that is placed facing downwards on an internal pad 105 disposed on the bottom surface of the recessed section 101, a piezoelectric resonator element 120 that is electrically and mechanically fixed onto a connection pad 116 disposed on a step 115 in the recessed section 101 by using a conductive adhesive 117, a metal cover 125 that seals the recessed section 101 of the insulating container, and a seam ring 126 that is integrated to the top surface of the outer frame of the insulating container 100.

In the piezoelectric resonator element 120, excitation electrodes and lead electrodes extending from the excitation electrodes are formed on both main surfaces of a piezoelectric substrate made of; for example, quartz crystal.

In this piezoelectric oscillator, the external electrode 102, the internal pad 105, the connection pad 116, and the seam ring 126 are connected by an internal conductor, which is not shown in the drawing.

The IC chip 110 is a bare chip constituting an oscillator circuit, a temperature compensated circuit, or the like, has a structure in which an integrated circuit and an electrode connected to it are placed to be exposed on one surface of a silicon substrate, and is flip chip mounted to the internal pads 105 formed on the inner bottom surface of the recessed section 101 with the surface having an electrode formed thereon facing downward by using a bump 111 or the like.

In addition, a piezoelectric oscillator that is structured such that an IC chip and the piezoelectric resonator element 120 are contained in the same space of the insulating container 100 is disclosed in patent document 1 and other documents.
[Patent Document 1] JP-A-2000-323927

### DISCLOSURE OF THE INVENTION

### PROBLEM TO BE SOLVED BY THE INVENTION

A related art surface mounting type quartz crystal oscillator as described above has a structure in which the IC chip 110 and the piezoelectric resonator element 120 are stacked in the height direction to be contained in the same space of the insulating container 100 and further the surface of the IC chip 110 contained in the insulating container 100 is not covered with a resin for protection so as to achieve reduction in thickness and height of the oscillator. Moreover, in a quartz crystal oscillator having such a structure, the IC chip 110 is processed to be thin for achieving further reduction in height.

However, if the IC chip 110 and the piezoelectric resonator element 120 are contained in the same space of the insulating container 100 in order to achieve reduction in thickness of the IC chip 110, dust such as silicon shavings attached to the surface of the IC chip 110 may be attached to the piezoelectric resonator element 120 to cause poor drive level dependency characteristics (hereinafter referred to as “DLD characteristics”).

The DLD characteristics are characteristics exhibiting changes of oscillation frequency due to drive level change of the piezoelectric resonator element 120, and it is found that there is a factor for poor DLD characteristics in the manufacturing processes as described below.

Usually in the manufacturing processes of an IC chip, if the IC chip is processed to be thin, a silicon wafer having an integrated circuit formed thereon is prepared, and after the surface of the integrated circuit (hereinafter referred to as a “front surface”) is covered with a protection film or a protection tape, the surface without the integrated circuit hereinafter referred to as a “back surface”) of the silicon wafer is polished with an abrasive. When the silicon wafer reaches a requested thickness, the abrasive and shavings are washed out with pure water. If the silicon wafer is polished as described above, however, a minute scratch is caused on the back surface by polishing, and particles of the abrasive and shavings may be fitted into the scratch. Silicon crystal wastes may also remain in a hangnail state on the back surface of the silicon wafer. Complete removal of such particle wastes cannot easily be performed by cleaning with pure water that has hitherto been practiced. Therefore, if such an IC chip as described above is placed in the same space as the piezoelectric resonator element so that the polished surface of the IC chip faces the piezoelectric element, particles and wastes are detached from the IC chip by a shock or the like applied to the oscillator and are attached to the piezoelectric resonator element (quartz crystal element). As a result, there have been cases of the particles and wastes causing poor DLD characteristics of the piezoelectric resonator element.

In view of the point as described above, the present invention is intended to provide a piezoelectric oscillator manufacturing method capable of preventing poor DLD characteristics that tend to occur in a piezoelectric oscillator in which a piezoelectric resonator element and an IC chip are sealed in the same package.

### MEANS FOR SOLVING THE PROBLEM

To achieve the above-described purpose, the invention according to claim 1 is directed to a method of manufacturing a piezoelectric oscillator including an insulating container for surface mounting with a recessed section on the top surface and an external electrode on the bottom surface, an IC chip mounted facing downwards on an internal pad provided on the bottom surface of the recessed section, a piezoelectric resonator element electrically and mechanically fixed onto a connection pad provided in the recessed section, and a metal cover sealing the recessed section of the insulating container; the method including a chemical polishing step for chemically polishing a surface without an integrated circuit of an IC chip wafer to which the IC chip as a bare chip is coupled, a cleaning step for cleaning the IC chip wafer after completion of the chemical polishing step, a cutting step for cutting the IC chip wafer into an individual piece, an IC chip mounting step for bonding the individual piece of IC chip facing downwards in the recessed section of the insulating container, a step for mounting the piezoelectric resonator element in the recessed section of the insulating container, and a sealing step for sealing the recessed section with the metal cover.

The invention according to claim 2 is directed to a method of manufacturing a piezoelectric oscillator including an insulating container for surface mounting with a recessed section on the top surface and an external electrode on the bottom surface, an IC chip mounted facing downwards on an internal pad provided on the bottom surface of the recessed section, a piezoelectric resonator element electrically and mechanically fixed onto a connection pad provided in the recessed section, and a metal cover sealing the recessed section of the insulating container, the method including a polishing step for polishing a surface without an integrated circuit of an IC chip wafer to which the IC chip as a bare chip is coupled, a chemical polishing step for chemically polishing a polished surface of the IC chip wafer, a cleaning step for cleaning the IC chip wafer after completion of the chemical polishing step, a cutting step for cutting the IC chip wafer into an individual piece, an IC chip mounting step for bonding the individual piece of IC chip facing downwards in the recessed section of the insulating container, a step for mounting the piezoelectric resonator element in the recessed section of the insulating container, and a sealing step for sealing the recessed section with the metal cover.

The invention according to claim 3 is directed to the method of manufacturing a piezoelectric oscillator according to claim 1 or 2, wherein in the cleaning step, chemical cleaning is performed.

The invention according to claim 4 is directed to the method of manufacturing a piezoelectric oscillator according to claim 3, wherein in the cleaning step, pure water cleaning is performed after chemical cleaning is performed.

The invention according to claim 5 is directed to a method of manufacturing a piezoelectric oscillator including an insulating container for surface mounting with a recessed section on the top surface and an external electrode on the bottom surface, an IC chip mounted facing downwards on an internal pad provided on the bottom surface of the recessed section, a piezoelectric resonator element electrically and mechanically fixed onto a connection pad provided in the recessed section, and a metal cover sealing the recessed section of the insulating container, the method including a polishing step for polishing a surface without an integrated circuit of an IC chip wafer to which the IC chip as a bare chip is coupled, a first cleaning step for chemically cleaning a polished surface of the IC chip wafer, a second cleaning step for cleaning the IC chip wafer with pure water after completion of the first cleaning, a cutting step for cutting the IC chip wafer into an individual piece, an IC chip mounting step for bonding the individual piece of IC chip facing downwards in the recessed section of the insulating container, a step for mounting the piezoelectric resonator element in the recessed section of the insulating container, and a sealing step for sealing the recessed section with the metal cover.

The invention according to claim 6 is directed to the method of manufacturing a piezoelectric oscillator according to any one of claims 1 to 5, wherein in the cutting step, the IC chip wafer is cut by using a laser beam.

The invention according to claim 7 is directed to a piezoelectric oscillator including an insulating container for surface mounting with a recessed section on the top surface and an external electrode on the bottom surface, an IC chip mounted facing downwards on an internal pad provided on the bottom surface of the recessed section, a piezoelectric resonator element electrically and mechanically fixed onto a connection pad provided in the recessed section, and a metal cover sealing the recessed section of the insulating container, wherein a surface of the IC chip facing the piezoelectric resonator element is an etched surface.

### EFFECTS OF THE INVENTION

According to the present invention, a chemical polishing treatment is applied to a surface without an integrated circuit of an IC chip wafer, so that no particles of an abrasive, shavings of a silicon wafer, or silicon crystal wastes remain, and thus poor DLD characteristics can be prevented from occurring even if a piezoelectric oscillator is structured such that an IC chip and a piezoelectric resonator element are contained in the same space.

In the present invention, chemical cleaning is applied onto a surface without an integrated circuit of an IC chip wafer to slightly etch the surface, so that no particles of an abrasive, shavings of a silicon wafer, or silicon crystal wastes remain, and thus poor DLD characteristics can be prevented from occurring even if a piezoelectric oscillator is structured such that an IC chip and a piezoelectric resonator element are contained in the same space.

Moreover, if an IC chip wafer is cut by using a laser beam in the cutting process, a chipping or a crack is not produced, and thus this is more effective as a measure against poor DLD characteristics.

### BEST MODE FOR CARRYING OUT THE INVENTION

The present invention will be described in detail below through embodiments illustrated in the accompanying drawings.

FIG. 1 is a drawing that shows the schematic structure of a surface mounting type quartz crystal oscillator according to an embodiment of the present invention, (a) and (b) showing a perspective view of the quartz crystal oscillator and a sectional view taken along the chain line A-A of the piezoelectric oscillator of (a), respectively.

A piezoelectric oscillator 1 shown in FIG. 1(a) (b) includes an insulating container 2 that has a recessed section 3 at the top surface and external electrodes 4 for surface mounting on the outer bottom, an IC chip 6 that is mounted facing downwards on an internal pad 5 disposed on the bottom surface of the recessed section 3, a piezoelectric resonator element 11 that is electrically and mechanically fixed onto a connection pad 8 disposed on the top surface of the outer frame of the insulating container 2 using a conductive adhesive 9, a metal cover 13 that seals the recessed section 3 of the insulating container 2, a seam ring 12 that is integrated to the top surface of the outer frame of the insulating container 2, and the like. In the piezoelectric resonator element 11, excitation electrodes and lead electrodes extending from the excitation electrodes are formed on both main surfaces of a piezoelectric substrate made of for example, quartz crystal.

In the piezoelectric oscillator 1 like this, the external electrode 4, the internal pad 5, the connection pad 8, and the seam ring 12 are connected by an internal conductor, which is not shown in the drawing. The IC chip 6 is a bare chip constituting an oscillator circuit, a temperature compensated circuit, or the like, has a structure such that an integrated circuit and an electrode connected to the integrated circuit are placed to be exposed on one surface of a silicon substrate, and is flip-chipped to the internal pads 5 formed on the inner bottom surface of the recessed section 3 with the surface having an electrode formed thereon facing downwards by using connecting members such as bumps 7.

In the piezoelectric oscillator 1 of the present embodiment, the back surface of the IC chip 6 mounted on the insulating container 2 is etched to form an etching surface 20, so that shavings produced during thinly polishing of the IC chip 6 do not remain on the back surface, which is positioned at the top surface side, of the IC chip 6. Thus, poor DLD characteristics can be prevented from occurring in a single seal type piezoelectric oscillator having the IC chip 6 and the piezoelectric resonator element 11 that are contained in the same space.

A method of manufacturing the surface mounting type quartz crystal oscillator shown in FIG. 1 will be described below.

FIGS. 2 and 3 are drawings illustrating manufacturing procedures of the surface mounting type quartz crystal oscillator according to the first embodiment.

In this case, first, a silicon wafer (IC chip wafer) 31 on which an integrated circuit is made by integrated circuit fabrication processes, which are not shown in the drawings, is prepared in step Si shown in FIG. 2. The silicon wafer 31 like this is made in a state in which a large number of IC chips as bare chips mentioned above are coupled thereto.

Next, in step S2, a chemical polishing treatment is applied to the back surface of the silicon wafer 31, that is, the surface on which the integrated circuit is not made. The chemical polishing treatment is etching with an alkaline solution such as potassium hydrate or polishing by combination use of an etchant such as an alkaline solution and an abrasive coating (abrasive). In this case, silica particles, for example, are used as the abrasive.

After the etching treatment in the above step S2 is completed, the silicon wafer 31 is cleaned in step S3, and after cleaning is completed, a tape is attached onto the whole of one surface of the silicon wafer 31 in step S4. Then, in step S5, the silicon wafer 31 is cut with a cutter 32 in such a cutting line as shown, so that a large number of IC chips 6 are taken out from the silicon wafer 31. Then, in the next step S6, the tape attached onto the IC chips 6 is detached. In addition, when the silicon wafer is cut, cutting wastes should be washed away. At this time, the tape is cut in half along the thickness direction.

The IC chip 6 obtained in the above step S6 is flip chip mounted on the internal pads 5 of the insulating container 2 with the front surface (integrated circuit surface) of the IC chip 6 facing downwards by using, for example, a suction tool 41 capable of sucking the IC chip 6 in step S7 shown in FIG. 3. In this case, at the top surface side of the IC chip 6 mounted on the insulating container 2 is the etching surface 20 that has been etched by a chemical polishing treatment.

In the subsequent step S8, the piezoelectric resonator element 11 is connected onto the connection pad 8 of the insulating container 2 by using the conductive adhesive 9, and thereafter, in step S9, the metal cover 13 is attached to the seal ring 12 on the top surface of the insulating container 2 so that the inside of the insulating container 2 is sealed in an airtight manner. Thus the surface mounting type quartz crystal oscillator shown in the above FIG. 1 can be obtained.

If a piezoelectric oscillator is manufactured as described above, no particles of an abrasive, shavings of a silicon wafer, or silicon crystal wastes remain on the back surface of the IC chip 6 even if polishing to make the IC chip 6 more thinner is performed in order to make the piezoelectric oscillator more thinner, and it is thereby possible to prevent poor DLD characteristics that have hitherto occurred in piezoelectric oscillators of single seal type.

Next, manufacturing procedures of a surface mounting type quartz crystal oscillator according to a second embodiment will be described.

In this case, first, the silicon wafer 31 on which an integrated circuit is made is prepared in step S11 shown in FIG. 4. Next, after a treatment of polishing the back surface of the silicon wafer 31 is performed in step S12, a chemical polishing treatment is applied to the polished surface in step S13. After completion of the chemical polishing treatment in step S13, the silicon wafer 31 is cleaned in step S14 and, after being cleaned, is manufactured by the procedures of step S4 and the following steps shown in FIG. 2, which are described earlier. That is, after a tape is attached onto the whole of one surface of the silicon wafer 31, the silicon wafer 31 is cut, so that the IC chip 6 is taken out, and then the tape attached onto the IC chip 6 is detached. Thereafter, the IC chip 6 is flip chip mounted by using the suction tool 41, and further, the piezoelectric resonator element 11 is mounted and the inside of the insulating container 2 is sealed in an airtight manner, thereby making it possible to obtain the surface mounting type quartz crystal oscillator shown in FIG. 1. In this case, since the front surface of the silicon wafer 31 is eventually a surface onto which etching is applied, no particles of an abrasive, shavings of a silicon wafer, or silicon crystal wastes remain on the back surface of the IC chip 6, allowing prevention of the poor DLD characteristics.

Next, manufacturing procedures of a surface mounting type quartz crystal oscillator according to a third embodiment will be described.

In this case, first, the silicon wafer 31 on which an integrated circuit is made is prepared in step S21 shown in FIG. 5. Next, after a treatment of polishing the back surface of the silicon wafer 31 in step S22, chemical cleaning is applied onto the polished surface in step S23. In the chemical cleaning, after cleaning is performed by using, for example, a dilute etchant, purifying is performed by using a fluoride solution such as hydrogen fluoride water, an ammonia solution, or a hydrochloric acid solution as required. As the dilute etchant, a mixture of ammonia, hydrogen peroxide solution, and water with the ratio of 1:1:5 is used. After the chemical cleaning is performed in the above step S23, the silicon wafer 31 is cleaned with pure water in step S24 and, after completion of cleaning, is manufactured by the procedures of step S24 and the following steps shown in FIG. 2 in the same manner as above, that is, by attaching a tape onto the whole of one surface of the silicon wafer 31, thereafter cutting the silicon wafer 31, so that the IC chip 6 is taken out, and then detaching the tape attached onto the IC chip 6. Thereafter, the IC chip 6 is flip chip mounted by using the suction tool 41, and further, the piezoelectric resonator element 11 is mounted and the inside of the insulating container 2 is sealed in an airtight manner, thereby making it possible to obtain the surface mounting type quartz crystal oscillator shown in FIG. 1.

In this case, since the front surface of the silicon wafer 31 is slightly removed by chemical cleaning, wastes or the like caught in a groove caused by polishing can be removed, and therefore no particles of an abrasive, shavings of a silicon wafer, or silicon crystal wastes remain on the back surface of the IC chip 6 in the same manner as mentioned above.

In addition, in the above manufacturing processes of a quartz crystal resonator according to the first and second embodiments, chemical cleaning may be performed in step S3 (S14). Chemical cleaning and pure water cleaning may be performed in step S3 (S14). In this case, pure water cleaning should be performed after chemical cleaning is performed.

If the silicon wafer 31 is cut by using a laser beam in step S5, a chipping or a crack produced in cutting by using a dicing blade is not produced in the silicon wafer 31, and thus it is more effective for measures against poor DLD characteristics to cut the silicon wafer 31 by using a laser beam.

In this embodiment, the connection pad 8 to connect the piezoelectric resonator element 11 is provided on the top surface of the insulating container 2 and the seam ring 12 to connect the metal cover 13 is disposed on the periphery of the connection pad 8 so that the IC chip 6 does not contact the piezoelectric resonator element 11 and the piezoelectric resonator element 11 does not contact the metal cover 13, but this is just an example. The present invention can also be applied at least to a piezoelectric oscillator having a structure in which an IC chip and the piezoelectric resonator element 11 are disposed in the same space of the insulating container. It is to be understood that the present invention can also be applied to, for example, a piezoelectric oscillator having such a structure as shown in FIG. 6.

### BRIEF DESCRIPTION OF THE DRAWINGS

FIG. 1 A drawing showing a schematic structure of a surface mounting type quartz crystal oscillator according to an embodiment of the present invention.

FIG. 2 A drawing showing manufacturing procedures of a surface mounting type quartz crystal oscillator according to the first embodiment.

FIG. 3 A drawing showing manufacturing procedures of the surface mounting type quartz crystal oscillator according to the first embodiment.

FIG. 4 A drawing showing manufacturing procedures of the surface mounting type quartz crystal oscillator according to the second embodiment.

FIG. 5 A drawing showing manufacturing procedures of the surface mounting type quartz crystal oscillator according to the third embodiment.

FIG. 6 A drawing showing a schematic structure of a related art surface mounting type quartz crystal oscillator.

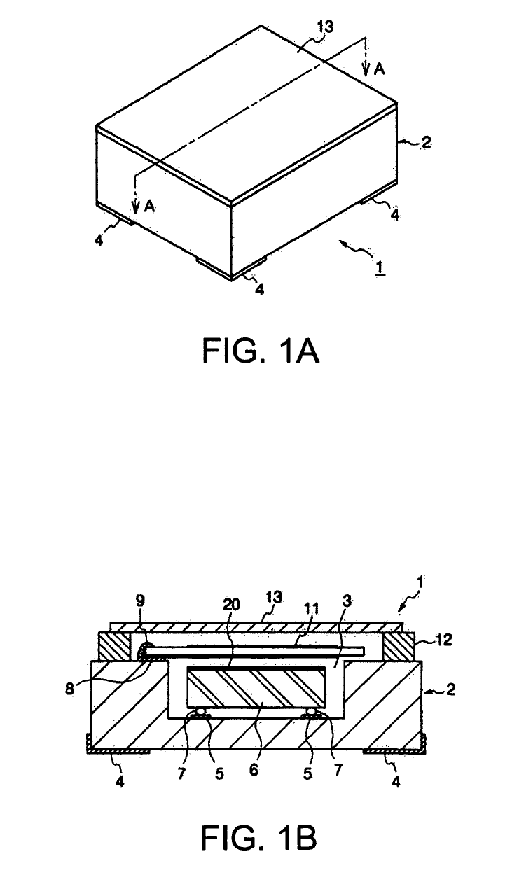

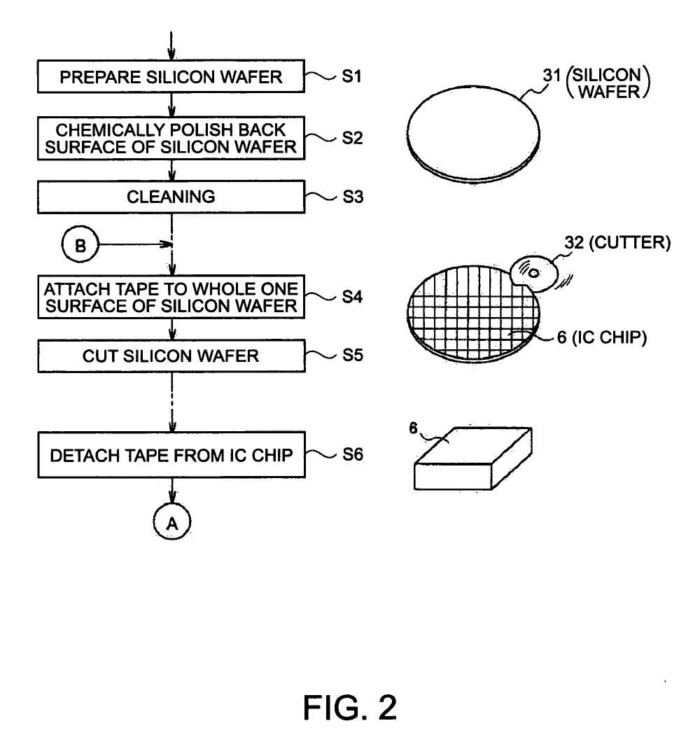

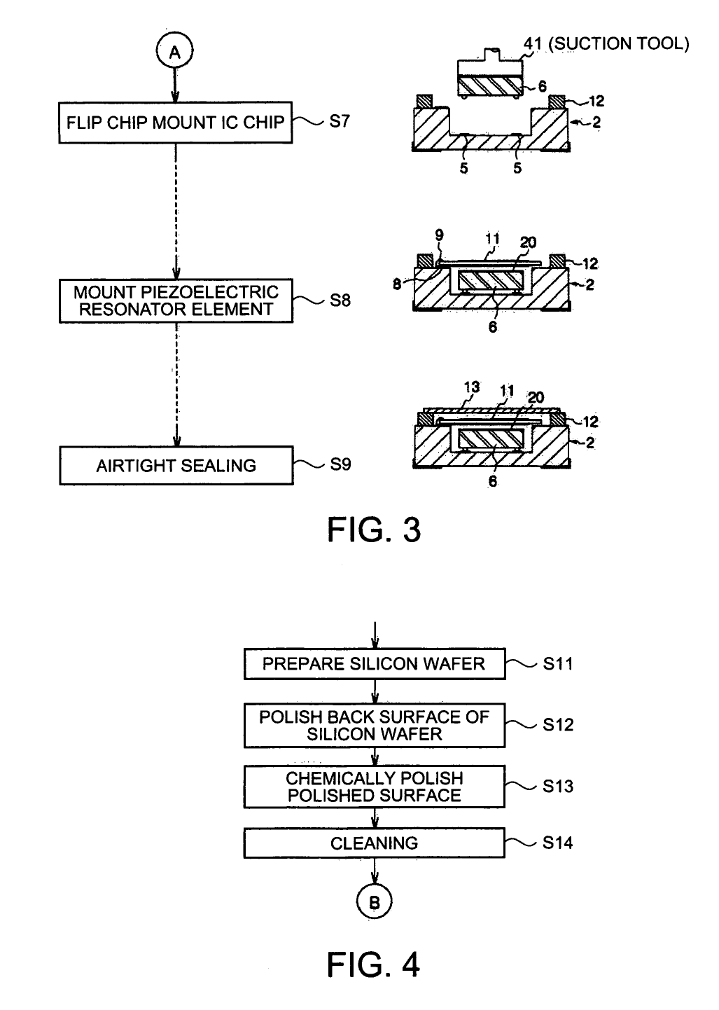

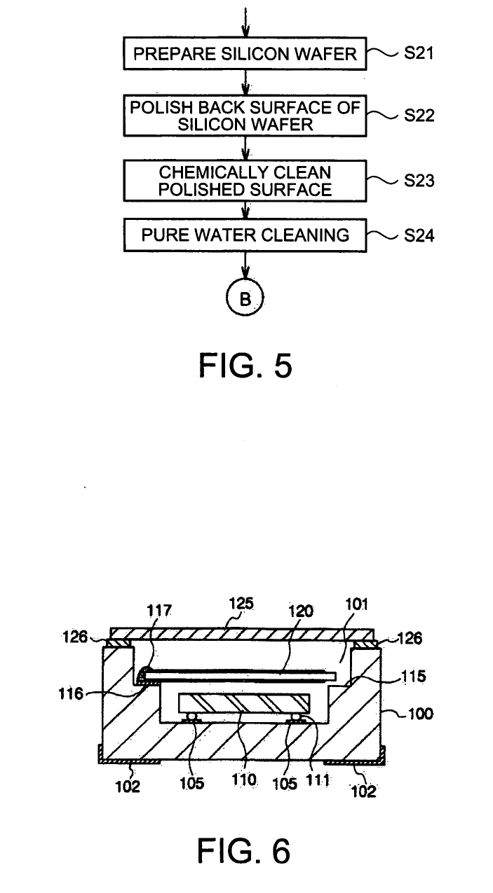

### DESCRIPTION OF REFERENCE NUMERALS

1: piezoelectric oscillator, 2: insulating container, 3: recessed section, 4: external electrode, 5: internal pad, 6: IC chip, 7: electrode, 8: connection pad, 9: conductive adhesive, 11: piezoelectric resonator element, 12: seam ring, 13: metal cover

1. (canceled)

2. (canceled)

3. (canceled)

4. (canceled)

5. (canceled)

6. (canceled)

7. (canceled)

8. A piezoelectric oscillator, comprising:
an IC chip in which an integrated circuit is formed on one surface;
a piezoelectric resonator element;
a container that stores the IC chip and the piezoelectric resonator element in a same space; and
the IC chip being mounted in the container such that the surface on which the integrated circuit is formed faces downwards, and a surface of the IC chip on which the integrated circuit is not formed is an etched surface on which an etching process has been performed.

9. The piezoelectric oscillator as set forth in claim 8, the piezoelectric resonator element being arranged opposite to an upper side of the etched surface of the IC chip.

10. The piezoelectric oscillator as set forth in claim 8, the etching process being a chemical polishing process.

11. The piezoelectric oscillator as set forth in claim 8, the etching process being a chemical cleaning process.

12. The piezoelectric oscillator as set forth in claims 8, the IC chip being a piece made by cutting a silicon wafer with a laser beam.

13. A method of manufacturing a piezoelectric oscillator, comprising:
preparing a piezoelectric resonator element and a facedown mount-type IC chip;
etching a top surface of the IC chip; and
storing the IC chip and the piezoelectric resonator element in a same space of the container.

14. The method of manufacturing a piezoelectric oscillator as set forth in claim 13,
the step of storing the IC chip and the piezoelectric resonator element in the same space of the container further including that the piezoelectric resonator element is stored so as to be arranged on the top side of the surface on which the etching process of the IC chip has been performed.

15. The method of manufacturing a piezoelectric oscillator as set forth in claim 13,
the etching process being a chemical polishing process.

16. The method of manufacturing a piezoelectric oscillator as set forth in claim 13,
the etching process being a chemical cleaning process.

17. The method of manufacturing a piezoelectric oscillator as set forth in claim 13,
the etching process being a step in which the surface on which the integrated circuit of the IC chip wafer coupled with the IC chip is not formed is processed.

18. The method of manufacturing a piezoelectric oscillator as set forth in claim 13,
the IC chip being a piece made by cutting the IC chip wafer with a laser beam.
